(19) United States
(12) Patent Application Publication
(10) Pub. No.: US 2008/0230918 A1
(43) Pub. Date: Sep. 25, 2008

(54) SEMICONDUCTOR INTEGRATED CIRCUIT AND DESIGN METHOD OF SIGNAL TERMINALS ON INPUT/OUTPUT CELL

(76) Inventor: Masahiro Gion, Kyoto (JP)

Correspondence Address: MCDERMOTT WILL & EMERY LLP, 600 13TH STREET, NW, WASHINGTON, DC, 20005-3096, US

(21) Appl. No.: 12/048,956

(22) Filed: Mar. 14, 2008

(30) Foreign Application Priority Data
Mar. 22, 2007 (JP) 2007-074828

(51) Int. Cl. H01L 23/48; G06F 9/45

(52) U.S. Cl. 257/774; 257/775; 716/10; 257/E23.174; 257/E23.169

(57) ABSTRACT

A semiconductor integrated circuit, including an input/output cell including signal terminals, wherein the signal terminal of the input/output cell is connected to an internal circuit via an interconnect wiring. The signal terminal of the I/O cell includes a plurality of (e.g., four) conductive layers. Each pair of adjacent ones of the plurality of conductive layers are connected together by a via. One of the plurality of conductive layers to which a via of the largest diameter is connected (e.g., the fourth conductive layer) is formed with a width such that only one of the largest-diameter via can be accommodated. Therefore, it is possible to suppress the migration of atoms from the interconnect wiring to the input terminal of the I/O cell, and to suppress the open failure of the via formed on the interconnect wiring.

### CROSS REFERENCE TO RELATED APPLICATIONS

This Non-provisional application claims priority under 35 U.S.C. §119(a) on Patent Application No. 2007-074828 filed in Japan on Mar. 22, 2007, the entire contents of which are hereby incorporated by reference.

### BACKGROUND OF THE INVENTION

The present invention relates to a semiconductor integrated circuit employing a standard cell architecture, and more particularly to the structure of signal terminals on input/output cells.

FIG. 9A shows a part of a conventional semiconductor integrated circuit employing a standard cell architecture, in which an internal circuit I including a signal processing circuit, etc., is provided within a semiconductor chip C, with many input/output cells 30 being arranged in parallel to one another along the periphery of the semiconductor chip C. Each input/output cell 30 is connected to the internal circuit I by interconnect wirings 31. Signals are input to, and output from, the input/output cells 30 via an electrode bump 33, which is provided at the peripheral end of each input/output cell 30.

Referring to an enlarged view of FIG. 9B, each input/output cell 30 includes one or more (three in the illustrated example) signal terminals 30a arranged side by side at one end thereof closer to the internal circuit I, and the interconnect wirings 31 are connected to the signal terminals 30a. The signal terminals 30a of the input/output cell 30 are broader than the interconnect wirings 31. Forming the signal terminals 30a with a large width improves the freedom in making the connection with the interconnect wirings 31. Such a structure is disclosed in, for example, Patent Document 1 (Japanese Patent No. 2707585).

The miniaturization of semiconductor integrated circuits and the transition of wiring materials thereof have led to a new problem as follows. Referring to FIG. 10, during a heat treatment, or the like, of a semiconductor integrated circuit in which a via 42 is provided on a narrow branch wiring 41 extending from a broad wiring 40, a large number of atoms of the branch wiring 41 migrate from the narrow branch wiring 41 toward the broad wiring 40 as indicated by an arrow in FIG. 10, and a large number of atoms of the via 42 also migrate toward the broad wiring 40. The migration of atoms may deteriorate the connection between the via 42 and the narrow branch wiring 41, resulting in a near disconnection therebetween and causing an open failure of the via 42. When there is an open failure of the via 42, a current flow from the via 42 to the narrow branch wiring 41 and the broad wiring 40 and a current flow in the reverse direction are limited or blocked, preventing the normal operation. Such a phenomenon caused by the migration of atoms is discussed in Non-Patent Document 1 (Norio OKADA, et al., “Thermal Stress of 140 nm-width Cu damascene interconnects”, IEEE International Interconnect Technology Conference 2002, see FIG. 9) as a problem encountered in miniaturization.

Referring to FIG. 11, the present inventor has discovered that the connection architecture between the signal terminals 30a of the input/output cell 30 and the interconnect wirings 31 in the semiconductor chip C of FIG. 9A is responsible for the open failure of a via caused by the migration of atoms shown in FIG. 10. Specifically, still referring to FIG. 11, the interconnect wiring 31 corresponds to the narrow branch wiring 41 of FIG. 10, the signal terminal 30a corresponds to the broad wiring 40 of FIG. 10, and a via 32 provided on the interconnect wiring 31 corresponds to the via 42 of FIG. 10. Thus, there is an increased possibility for an open failure to occur with the via 32 formed on the interconnect wiring 31 as shown in FIG. 11.

The reduction in the yield due to the open failure as described above may be avoided for example by increasing the number of the vias 32 to two or more (two in the illustrated example) as shown in FIG. 12 so as to reduce the possibility for an open failure to occur with a via due to the migration of atoms, or by spacing the via 32 formed on the interconnect wiring 31 away from the signal terminal (broad wiring) 30a as shown in FIG. 13 so as to reduce the migration of atoms.

However, these methods impose limitations on the layout of the vias 32 and the interconnect wirings. Since signal wirings in the semiconductor chip C are routed very closely together, such layout limitations will increase the total area of the semiconductor chip C and the cost of the semiconductor integrated circuit.

Patent Document 1 fails to pay particular attention to vias. With the current level of miniaturization, it has become very important to design a layout with particular attention to vias. Apparently, the level of miniaturization will further advance, and the open failure of a via due to the migration of atoms will accordingly become a more serious issue in the future.

### SUMMARY OF THE INVENTION

An object of the present invention is to provide a semiconductor integrated circuit including input/output cells having signal terminals thereon in which an open failure of a via is effectively prevented by employing a connection architecture between the signal terminals on the input/output cells and the interconnect wirings that is different from the connection architecture shown in FIG. 10, with which an open failure of a via occurs due to the migration of atoms.

In order to achieve an object set forth above, the present invention employs a structure where a signal terminal on an input/output cell includes a plurality of conductive layers each having a width that is not larger than that of an interconnect wiring connected thereto.

Specifically, a semiconductor integrated circuit of the present invention includes: an I/O cell including one or more signal terminals and being capable of inputting, outputting or inputting/outputting a signal via the signal terminal; and an interconnect wiring for connecting the signal terminal of the I/O cell to an internal circuit, wherein: the signal terminal of the I/O cell is formed by a plurality of conductive layers; adjacent ones of the plurality of conductive layers are connected together by one or more vias; and a broadest conductive layer, being a broadest one of the plurality of conductive layers, has a width such that only one largest-diameter via having a largest diameter among all the vias can be accommodated.

In one embodiment of the present invention, the plurality of conductive layers have a same width.

In one embodiment of the present invention, at least two of the plurality of conductive layers have different widths from each other.

In one embodiment of the present invention, the broadest conductive layer is an uppermost one of the plurality of conductive layers and has a largest thickness among the plurality of conductive layers; and the largest-diameter via is a via that connects the uppermost conductive layer with another one of the plurality of conductive layers immediately below the uppermost conductive layer.

In one embodiment of the present invention, a width of the broadest conductive layer is smaller than twice the diameter of the largest-diameter via.

In one embodiment of the present invention, a width of the broadest conductive layer is larger than the diameter of the largest-diameter via.

In one embodiment of the present invention, a width of the broadest conductive layer is equal to the diameter of the largest-diameter via.

In one embodiment of the present invention, a width of the broadest conductive layer is smaller than the diameter of the largest-diameter via.

In one embodiment of the present invention, for any pair of adjacent ones of the plurality of conductive layers, one or more vias for connecting the adjacent conductive layers together are arranged in a longitudinal direction of the conductive layers.

In one embodiment of the present invention, with vias other than the largest-diameter via, more than one of such vias are arranged in a width direction of the conductive layer to which the vias are connected.

In one embodiment of the present invention, one or more of the conductive layers to which the largest-diameter via is not connected are narrow conductive layers, which are narrower than the broadest conductive layer.

In one embodiment of the present invention, a width of the narrow conductive layer is smaller than twice a diameter of the via connected to the narrow conductive layer.

In one embodiment of the present invention, a width of the narrow conductive layer is larger than a diameter of the via connected to the narrow conductive layer.

In one embodiment of the present invention, a width of the narrow conductive layer is equal to a diameter of the via connected to the narrow conductive layer.

In one embodiment of the present invention, a width of the narrow conductive layer is smaller than a diameter of the via connected to the narrow conductive layer.

A method for designing a signal terminal on an I/O cell of the present invention includes the steps of: determining a plurality of conductive layers to be used as the signal terminal on the I/O cell; obtaining a diameter of one of a plurality of vias each for connecting together adjacent ones of the plurality of conductive layers that has a largest diameter; and setting a width of one of the plurality of conductive layers to which the largest-diameter via is connected to such a width that only one of the largest-diameter via can be accommodated.

In one embodiment of the present invention, the method further includes the steps of: estimating an amount of current flow between adjacent ones of the plurality of conductive layers; calculating a number of vias through which the estimated amount of current can be conducted; and setting a length of the plurality of conductive layers to a length sufficient for covering the calculated number of vias.

Thus, according to the present invention, a signal terminal on an I/O cell includes a plurality of conductive layers, wherein the width of the broadest one of the plurality of conductive layers is limited to such a width that only one largest-diameter via can be accommodated. Therefore, with an interconnect wiring connected to any one of the plurality of conductive layers, the connection architecture is no longer a connection architecture that results in an open failure of a via due to the migration of atoms as shown in FIG. 10, thereby eliminating or reducing the migration of atoms from the interconnect wiring into one of the conductive layers of the signal terminal. As a result, vias can be freely arranged on the interconnect wiring, thus causing no restrictions in designing the layout of the vias and interconnect wirings. Thus, it is possible to suppress the increase in the area of the semiconductor chip and suppress the increase in the cost of the semiconductor integrated circuit.

### BRIEF DESCRIPTION OF THE DRAWINGS

FIG. 1A shows a part of a semiconductor integrated circuit (semiconductor chip) according to a first embodiment of the present invention, FIG. 1B is an enlarged view showing a portion indicated by a broken line circle in FIG. 1A.

FIG. 2 is a cross-sectional view taken along line A-A′ of FIG. 1B.

FIG. 3A is a cross-sectional view taken along line B-B′ of FIG. 1B, FIG. 3B shows a first variation of FIG. 3A, and FIG. 3C shows a second variation of FIG. 3A.

FIG. 4 shows a structure similar to that of FIG. 1B wherein an additional interconnect wiring is connected to the interconnect wiring by a via therebetween.

FIG. 5 is a cross-sectional view taken along line C-C′ of FIG. 4.

FIG. 6 corresponds to FIG. 3A, showing a second embodiment of the present invention.

FIG. 7A corresponds to FIG. 3A, showing a third embodiment of the present invention, FIG. 7B shows a first variation of FIG. 7A, and FIG. 7C shows a second variation of FIG. 7A.

FIG. 8 is a flow chart showing a method for designing a signal terminal on an I/O cell according to a fourth embodiment of the present invention.

FIG. 9A shows a part of a conventional semiconductor chip, and FIG. 9B is an enlarged view showing a portion indicated by a broken line circle in FIG. 9A.

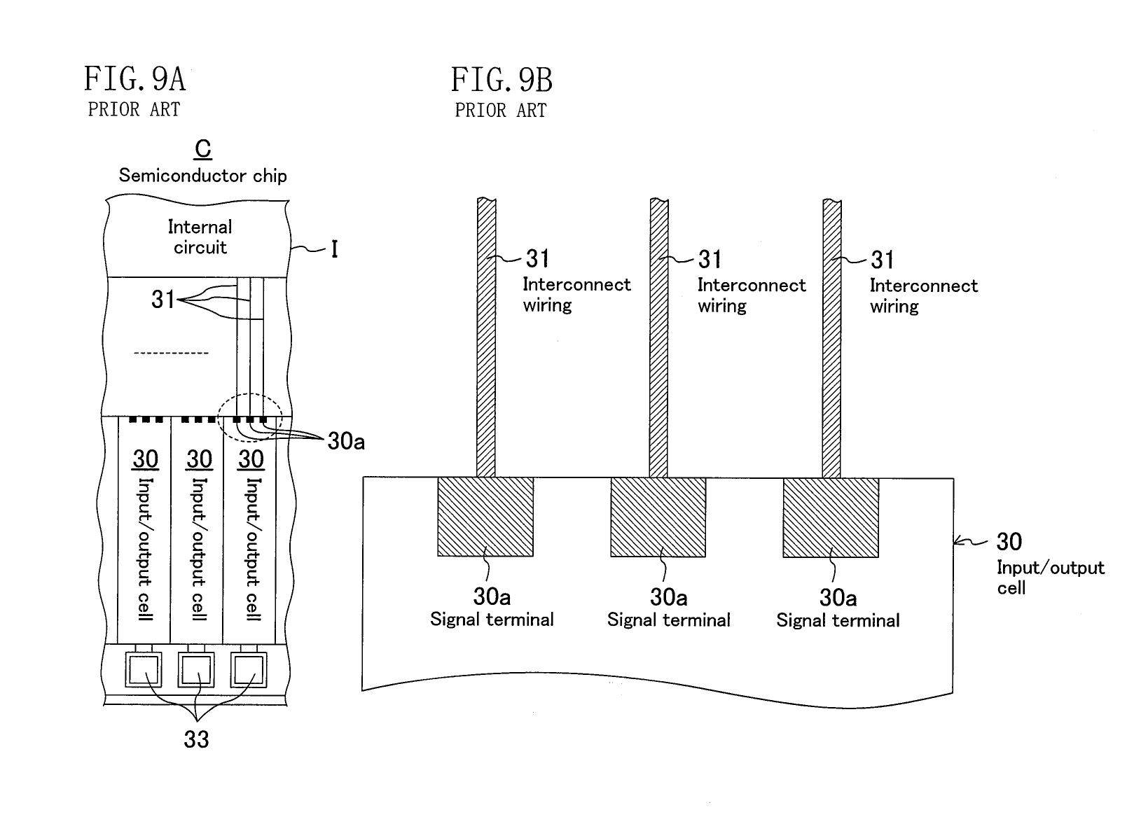

FIG. 10 shows how atoms flow from a narrow branch wiring toward a broad wiring.

FIG. 11 is a diagram showing the problem of the conventional structure where interconnect wirings are connected to signal terminals on an input/output cell.

FIG. 12 shows an alternative method aiming at solving the problem shown in FIG. 11.

FIG. 13 shows another alternative method for aiming at solving the problem shown in FIG. 11.

### DETAILED DESCRIPTION OF THE PREFERRED EMBODIMENTS

Preferred embodiments of the present invention will now be described with reference to the accompanying drawings.

### First Embodiment

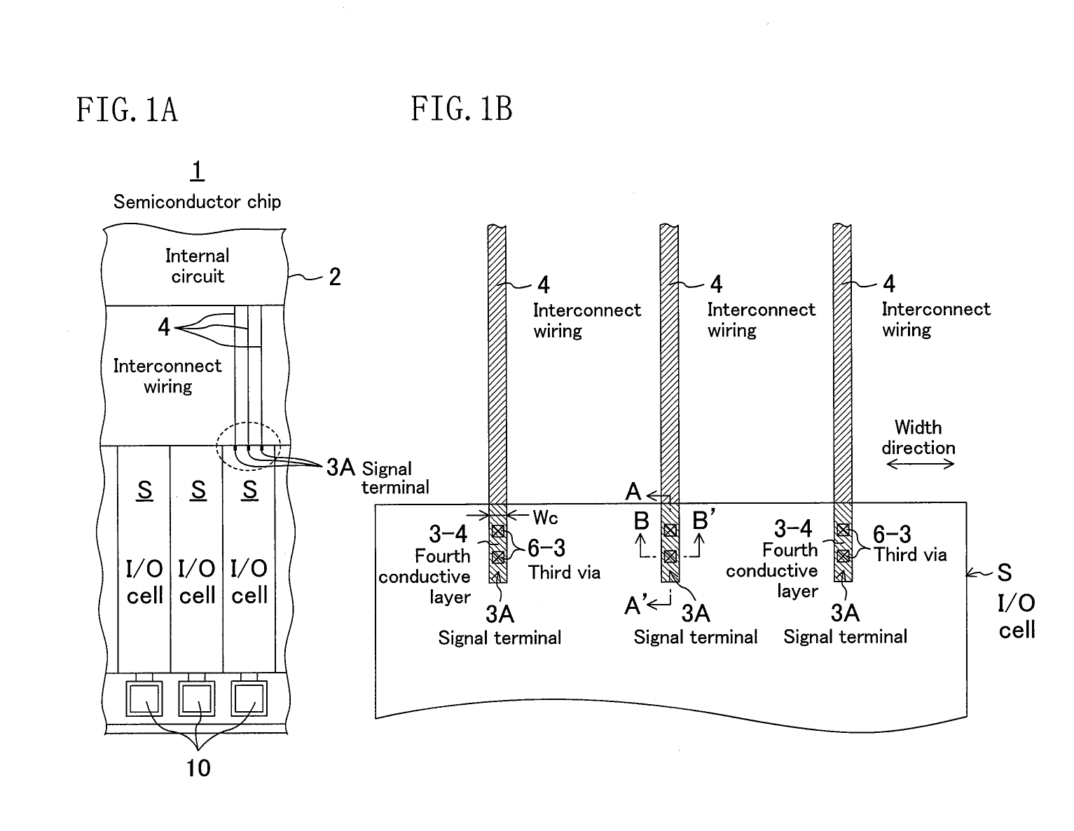

FIGS. 1A and 1B are plan views showing a semiconductor integrated circuit according to a first embodiment of the present invention.

Referring to FIG. 1A, a semiconductor chip 1 is a semiconductor integrated circuit employing a standard cell architecture. An internal circuit 2 including a signal processing circuit, etc., is provided within the semiconductor chip 1, with many I/O cells S being arranged in parallel to one another along the periphery of the semiconductor chip 1. Each I/O cell S is connected to the internal circuit 2 by interconnect wirings 4. Signals are input to, and output from, the I/O cells S via an electrode bump 10, which is provided at the peripheral end of each the I/O cell S. Each cell S is not limited to a cell capable of both inputting and outputting signals, but may be a cell only capable of either inputting or outputting signals. Such input cells, output cells and input/output cells are herein referred to collectively as I/O cells.

The connection architecture between the I/O cell S and the interconnect wiring 4 will now be described in detail. Referring to an enlarged view of FIG. 1B, each I/O cell S includes one or more (three in the illustrated example) signal terminals 3A arranged side by side at one end thereof closer to the internal circuit 2, and the interconnect wirings 4 are connected to the signal terminals 3A.

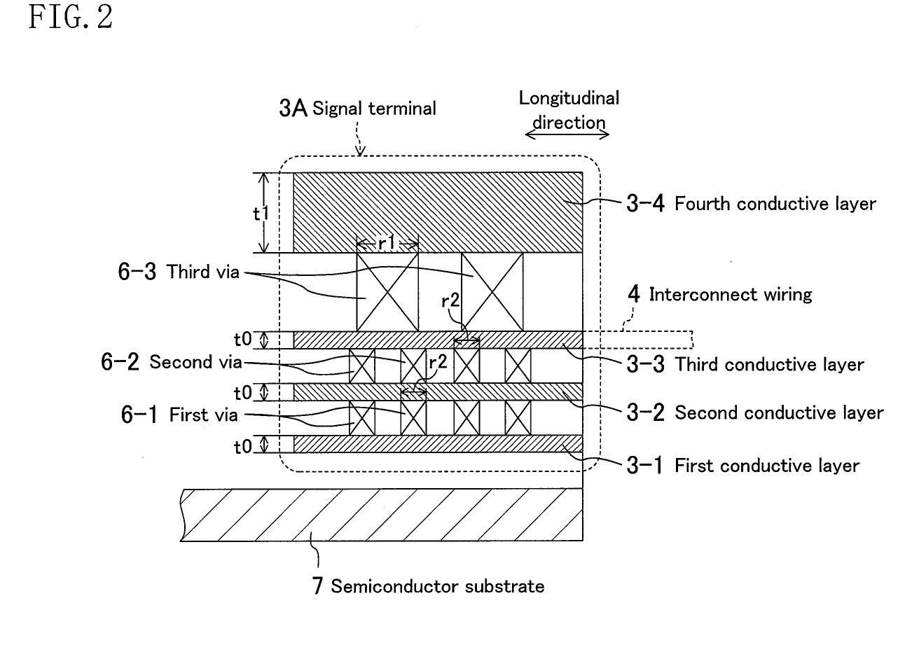

FIG. 2 shows the structure of each signal terminal 3A of the I/O cell S. FIG. 2 is a cross-sectional view taken along line A-A′ of FIG. 1B, i.e., a cross-sectional view taken in the longitudinal direction of the signal terminal 3A (the direction of a line extending from the I/O cell S to the internal circuit 2 via the interconnect wiring 4). Referring to FIG. 2, the signal terminal 3A includes a plurality of (four in the illustrated example) conductive layers. First, second and third conductive layers 3-1, 3-2 and 3-3 from the bottom are formed with the same thickness t0, and a fourth, top conductive layer 3-4 is the thickest layer formed with a thickness t1 greater than t0 (t1>t0). While different thicknesses are used in the present embodiment, all the conductive layers may be formed with the same thickness.

The conductive layers 3-1 to 3-4 are used together as the signal terminal 3A. For this purpose, referring to FIG. 2, the first conductive layer 3-1 and the second conductive layer 3-2 are connected together by four first vias 6-1 arranged in the longitudinal direction of the signal terminal 3A, the second conductive layer 3-2 and the third conductive layer 3-3 are connected together by four second vias 6-2 arranged in the longitudinal direction of the signal terminal 3A, and the third conductive layer 3-3 and the fourth conductive layer 3-4 are connected together by two third vias 6-3 arranged in the longitudinal direction of the signal terminal 3A. In order to electrically desirably connect two adjacent conductive layers, the diameter r1 of the third vias 6-3 used for connecting the thick fourth conductive layer 3-4 to the third conductive layer 3-3 is set to an increased diameter in proportion to the thickness of the fourth conductive layer 3-4. Thus, the third vias 6-3 are largest-diameter vias with the diameter r1 thereof being greater than the diameter r2 of the first and second vias 6-1 and 6-2 (r1>r2).

While a plurality of each of the first to third vias 6-1 to 6-3 are arranged in the longitudinal direction of the signal terminal 3A in the example shown in FIG. 2, the present invention is not limited to this, and there may be provided only one each of the vias 6-1 to 6-3. In FIG. 2, reference numeral 7 denotes a semiconductor substrate.

As shown in FIG. 2, the signal terminal 3A using a plurality of conductive layers improves the design freedom because the interconnect wirings 4 can be connected thereto by using any of the conductive layers. In the illustrated example, the interconnect wiring 4, which is shown by a broken line, is connected to the third conductive layer 3-3.

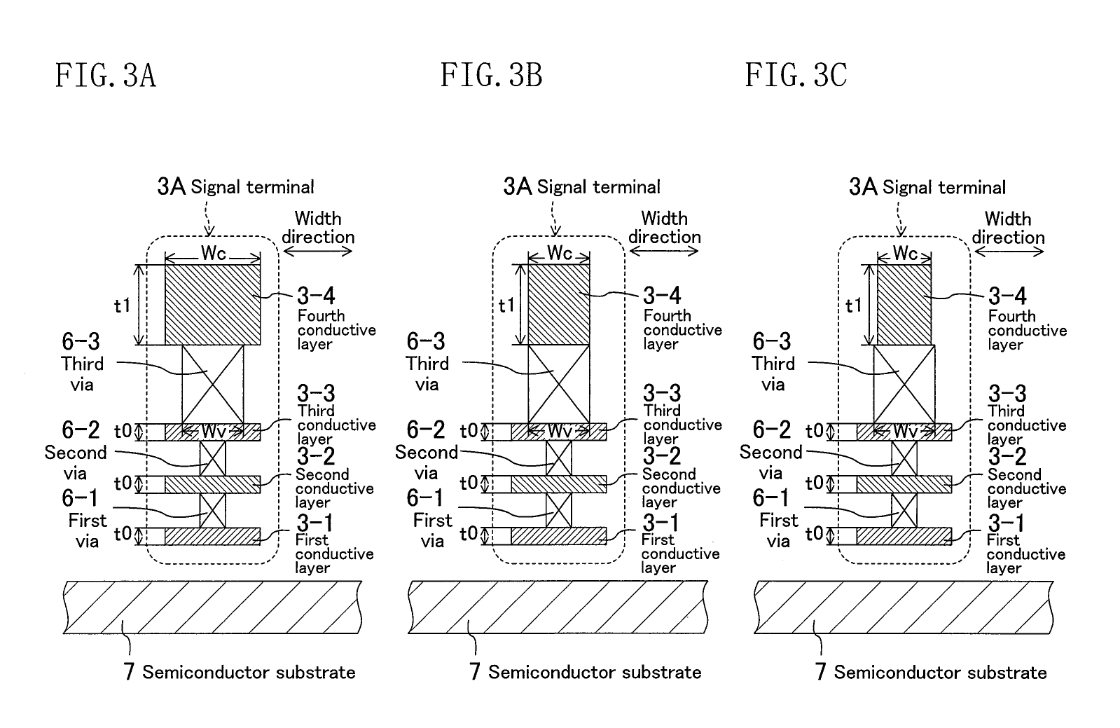

In the present embodiment, in order to effectively prevent an open failure of a via due to the migration of atoms, the conductive layers 3-1 to 3-4 of the signal terminal 3A are formed with as narrow a width as possible. The width should also not be too small to accommodate the first to third vias 6-1 to 6-3 for connecting adjacent conductive layers. Accordingly, the width of the conductive layers is, at most, such a width that one of the first to third vias 6-1 to 6-3 of the signal terminal 3A that has the largest diameter can be placed thereon. This will now be described in detail with reference to FIGS. 3A to 3C.

FIG. 3A is a cross-sectional view taken along line B-B′ of FIG. 1B showing the signal terminal 3A as viewed in the width direction thereof. Since the largest-diameter via among the first to third vias 6-1 to 6-3 of the signal terminal 3A is the third via 6-3 as can be seen from the figure, those of the conductive layers 3-1 to 3-4 of the signal terminal 3A to which the largest-diameter via 6-3 is connected, i.e., the third and fourth conductive layers 3-3 and 3-4, are the broadest conductive layers whose width Wc is set so that one of the largest-diameter via 6-3 can be accommodated. In FIG. 3A, not only the third and fourth conductive layers 3-3 and 3-4 but also the first and second conductive layers 3-1 and 3-2 are broadest conductive layers, and the first to fourth conductive layers 3-1 to 3-4 all have the same width Wc.

The structure where the width Wc of the broadest conductive layer is such that only one of the largest-diameter via (the third via 6-3) can be accommodated can also be seen in FIG. 1B.

In other words, the structure where the width Wc of the broadest conductive layer is such that only one of the largest-diameter via (the third via 6-3) is accommodated means that the width Wc of the broadest conductive layer is less than twice the diameter Wv of the largest-diameter via (the third via 6-3) (i.e., Wc<2·Wv). Therefore, as long as the width Wc of the broadest conductive layer satisfies Wc<2·Wv, the width Wc may be larger than (FIG. 3A), equal to (FIG. 3B) or smaller than (FIG. 3C) the diameter Wv of the largest-diameter via.

In FIGS. 1B and 2, a plurality of (two in the illustrated example) of the third vias (the largest-diameter vias) 6-3 are arranged in the longitudinal direction of the signal terminal 3A for the following reason. That is, the amount of current to flow between the fourth conductive layer 3-4 and the third conductive layer 3-3 can be estimated by calculation based on the required current capacity of the signal terminal 3A, and it may require two or more of the third vias 6-3 having the largest diameter Wv in order to allow the flow of this amount of current.

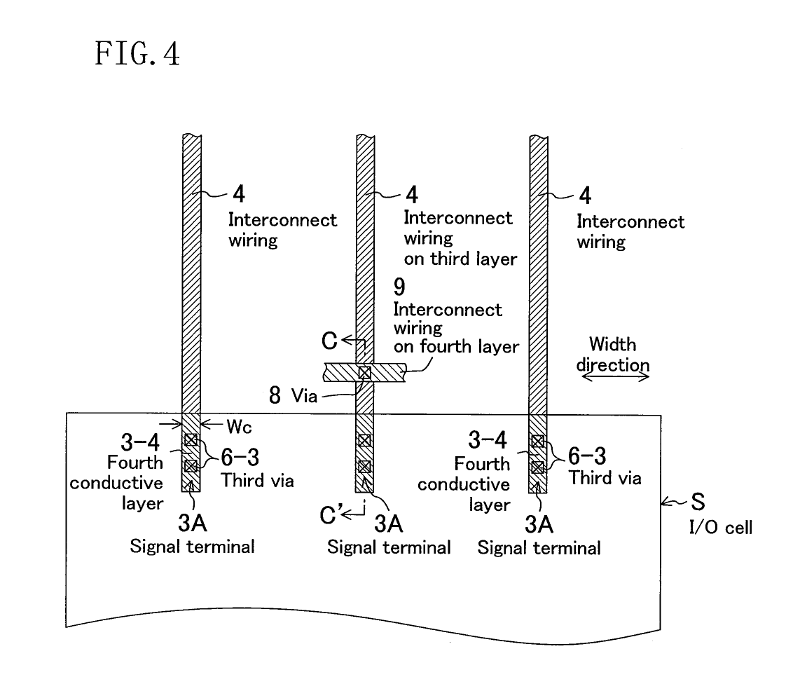

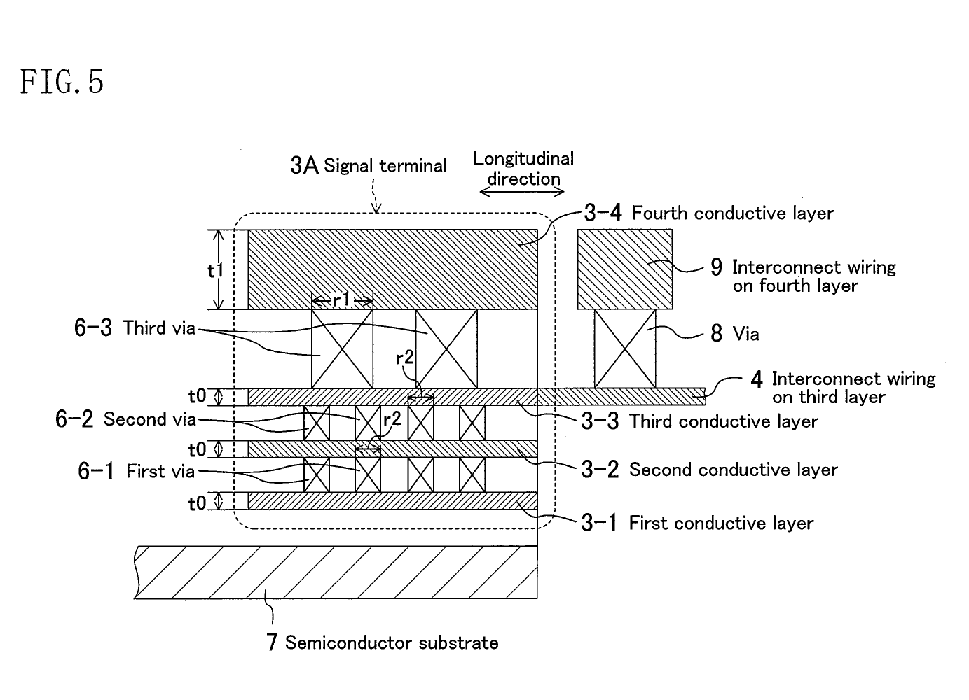

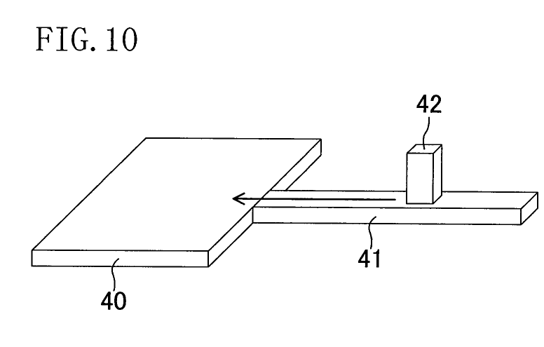

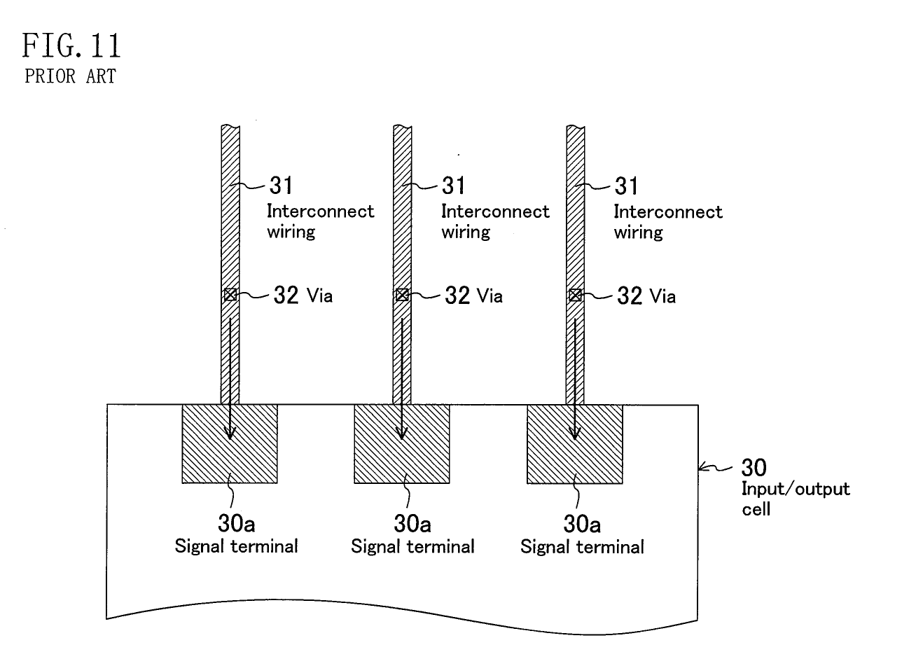

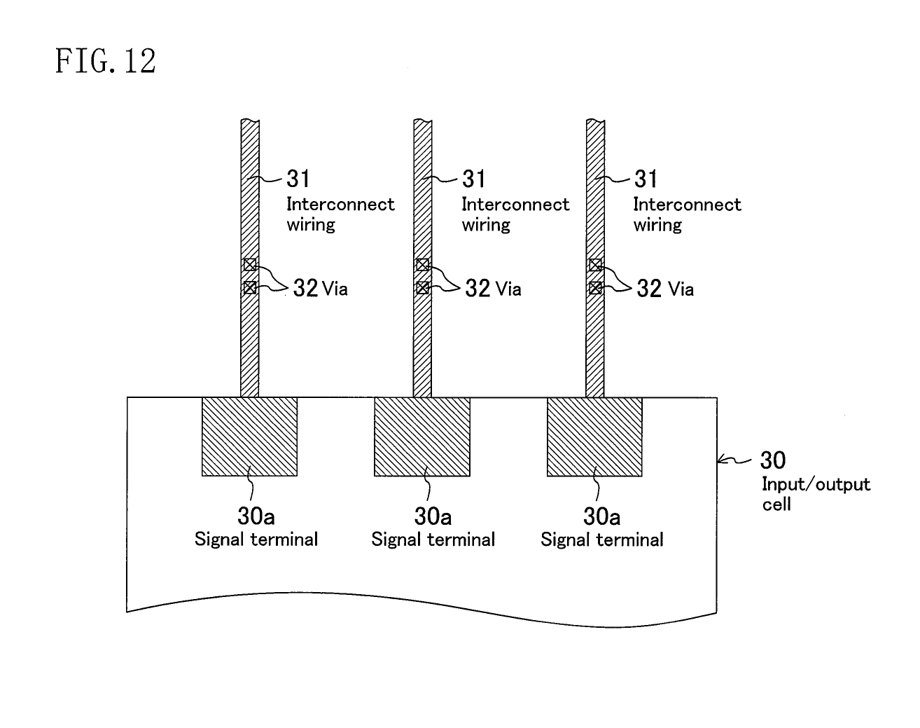

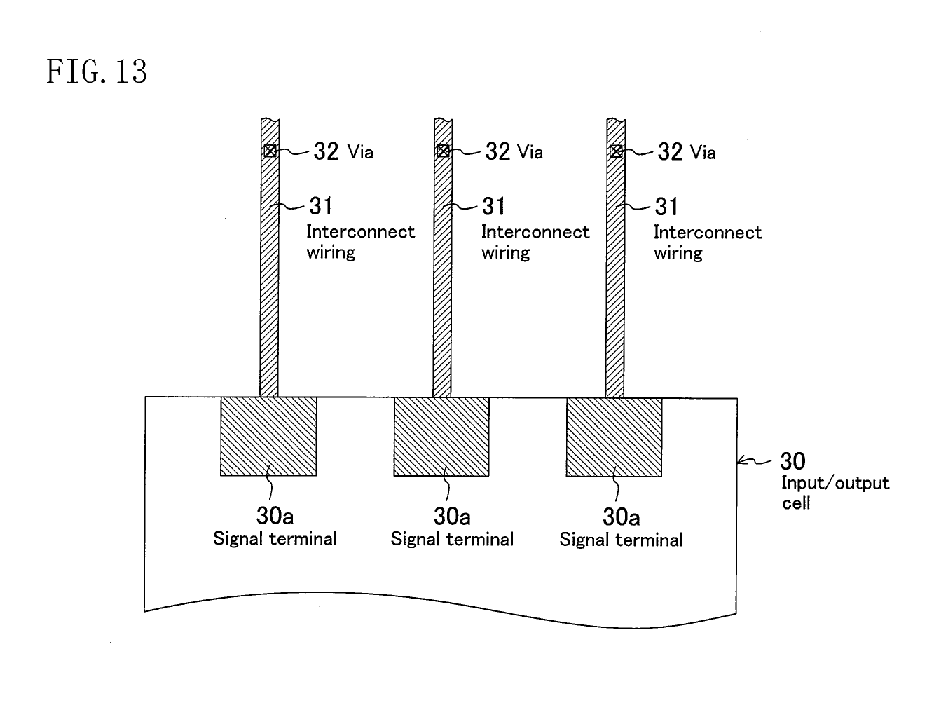

By employing the structure as shown in FIGS. 1A to 3C for the signal terminal 3A as described above, problems in the prior art can be solved as follows. Referring to FIG. 4 and FIG. 5 being a cross-sectional view taken along line C-C′ of FIG. 4, consider a case where the interconnect wirings 4 are connected to the third conductive layer 3-3 of the signal terminal 3A, for example. In this case, the width of the signal terminal 3A (i.e., the width Wc of each of the conductive layers 3-1 to 3-4) is set to be narrow and substantially equal to the width of the interconnect wiring 4, thus providing a structure different from that shown in FIG. 11 where narrow branch wirings are connected to broad wirings. Thus, the migration of atoms as shown in FIG. 10, i.e., the phenomenon in which atoms migrate from the interconnect wiring 4 toward the signal terminal 3A, is less likely to occur. Therefore, it is not necessary to provide a plurality of vias 32 on each interconnect wiring 31 as shown in FIG. 12, or to space the via 32 away from the signal terminal 30a as shown in FIG. 13, and it is thus possible to freely arrange a via 8 produced on the interconnect wiring 4 as shown in FIG. 4. For example, the via 8 can be placed close to the signal terminal 3A. Referring to FIGS. 4 and 5, the signal terminal 3A can be connected to a predetermined signal terminal (not shown) of the internal circuit (not shown) via the third conductive layer 3-3 and the interconnect wiring 4 formed in the same layer as the conductive layer 3-3, or connected to another predetermined signal terminal (not shown) of the internal circuit via the single via 8 formed on the interconnect wiring 4 of the third layer and an interconnect wiring 9 formed in the fourth layer.

Thus, according to the present embodiment, it is possible to effectively prevent an open failure of the via 8 due to the migration of atoms while maintaining a high design freedom such that interconnect wirings can be connected to any of the plurality of conductive layers. Moreover, since the prevention of the open failure of the via 8 does not restrict the design freedom of vias and wirings inside the semiconductor chip 1, it is possible with the improved design freedom to suppress the increase in the area of the semiconductor chip 1 and suppress the increase in the cost of the semiconductor integrated circuit.

### Second Embodiment

A second embodiment of the present invention will now be described.

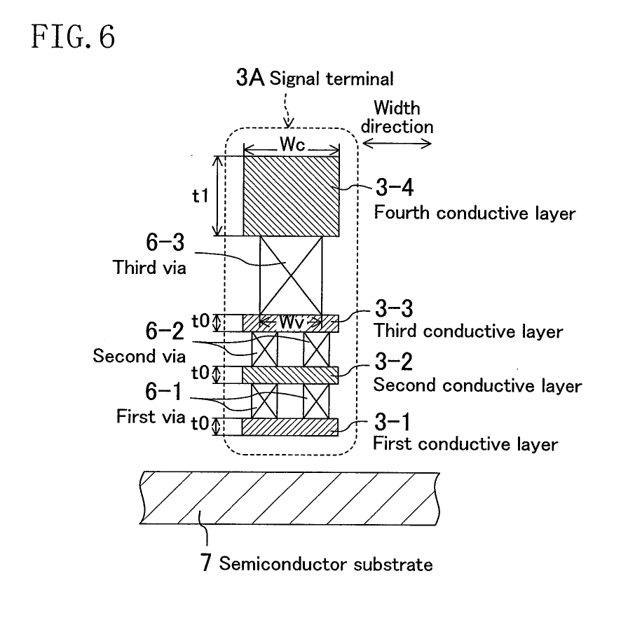

FIG. 6 is a cross-sectional view taken in the direction corresponding to line B-B′ of FIG. 1B (i.e., a cross-sectional view in the width direction of the signal terminal 3A), showing a semiconductor integrated circuit according to the second embodiment of the present invention. The present embodiment differs from the first embodiment shown in FIG. 3A in that a plurality of (two in the illustrated example) each of the first and second vias (the vias other than the largest-diameter via) 6-1 and 6-2 are arranged in the width direction of the signal terminal 3A.

Although only one each of the first via 6-1 and the second via 6-2 is provided in the width direction of the signal terminal 3A in the example shown in FIG. 3A, the diameter of the first via 6-1 and the second via 6-2 is smaller than that of the third via (the largest-diameter via) 6-3, and therefore a plurality of such vias may be provided in the width direction of the signal terminal 3A as shown in FIG. 6 as long as the structure allows such an arrangement.

Thus, in the present embodiment, the current flow through the first and second vias 6-1 and 6-2 can be distributed even more, further improving the via reliability.

### Third Embodiment

A third embodiment of the present invention will now be described.

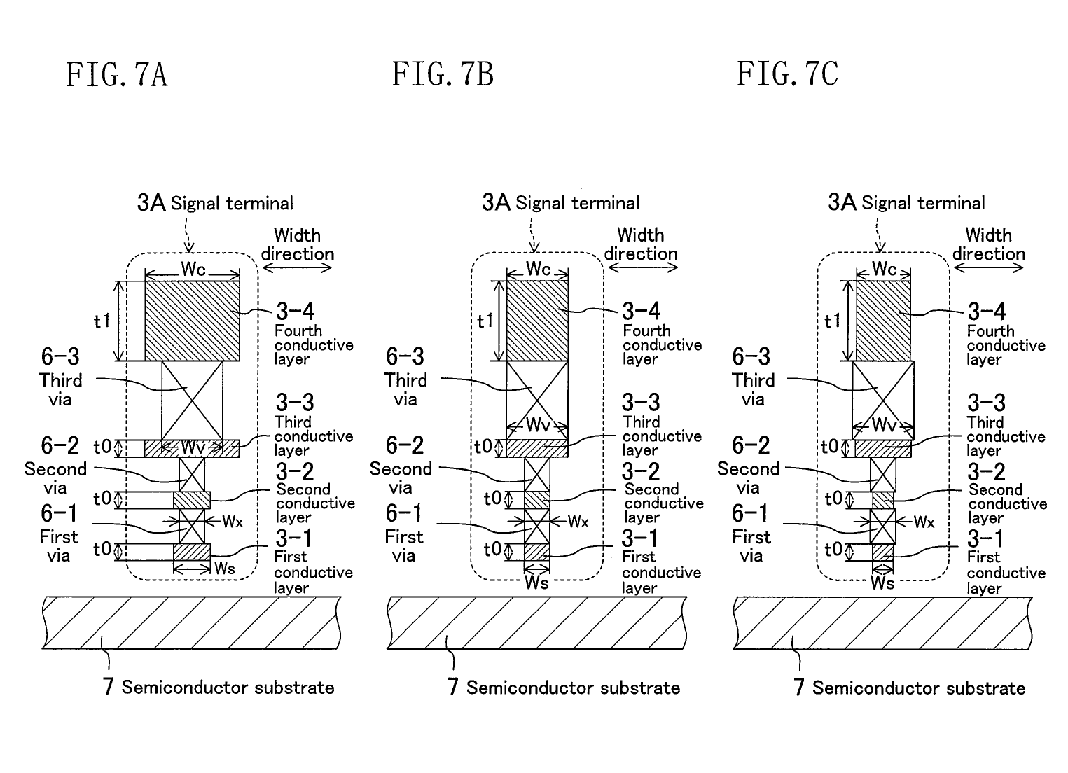

FIG. 7A is a cross-sectional view taken in the direction corresponding to line B-B′ of FIG. 1B (i.e., a cross-sectional view in the width direction of the signal terminal 3A), showing a semiconductor integrated circuit according to the third embodiment of the present invention. The present embodiment differs from the first embodiment shown in FIGS. 3A to 3C in that only the third and fourth conductive layers 3-3 and 3-4 are the broadest conductive layer, with the first and second conductive layers (conductive layers other than the broadest conductive layers) 3-1 and 3-2 being formed with a width smaller than that of the third and fourth conductive layers (the broadest conductive layers) 3-3 and 3-4.

Specifically, the first and second conductive layers 3-1 and 3-2 are formed with the same width as the third and fourth conductive layers 3-3 and 3-4 in the example shown in FIG. 3A. In contrast, in the example shown in FIG. 7A, since the vias connected to the first and second conductive layers 3-1 and 3-2 (vias other than the largest-diameter vias) have a small diameter, the first and second conductive layers 3-1 and 3-2 are formed with a smaller width Ws than the width Wc of the third and fourth conductive layers (broadest conductive layer) 3-3 and 3-4 (i.e., Ws<Wc). Thus, the first and second conductive layers 3-1 and 3-2 are narrow conductive layers that are narrower than the broadest conductive layers 3-3 and 3-4. The width Ws of the narrow conductive layers 3-1 and 3-2 is such that only one of the first via 6-1 connected to the narrow conductive layer can be accommodated. In other words, the width Ws of the narrow conductive layers 3-1 and 3-2 is smaller than twice the diameter Wx of the first via 6-1 (i.e., Ws<2·Wx).

Thus, as long as the conductive layers 3-1 to 3-4 are desirably connected together by vias therebetween, the conductive layers may have different widths. With such a structure, if the interconnect wiring 4 is connected to the second conductive layer 3-2, for example, it is possible to effectively prevent an open failure of a via (not shown) connected to the interconnect wiring 4 due to the migration of atoms, further improving the via reliability.

While the width Ws of the first and second conductive layers 3-1 and 3-2 is larger than the diameter of the first via 6-1 for connecting these conductive layers together in the example shown in FIG. 7A, the width Ws may be equal to (FIG. 7B) or smaller than (FIG. 7C) the diameter of the via 6-1, as with the examples shown in FIGS. 3B and 3C.

### Fourth Embodiment

A fourth embodiment of the present invention will now be described.

The present embodiment is directed to a method for designing a signal terminal on an I/O cell as described above.

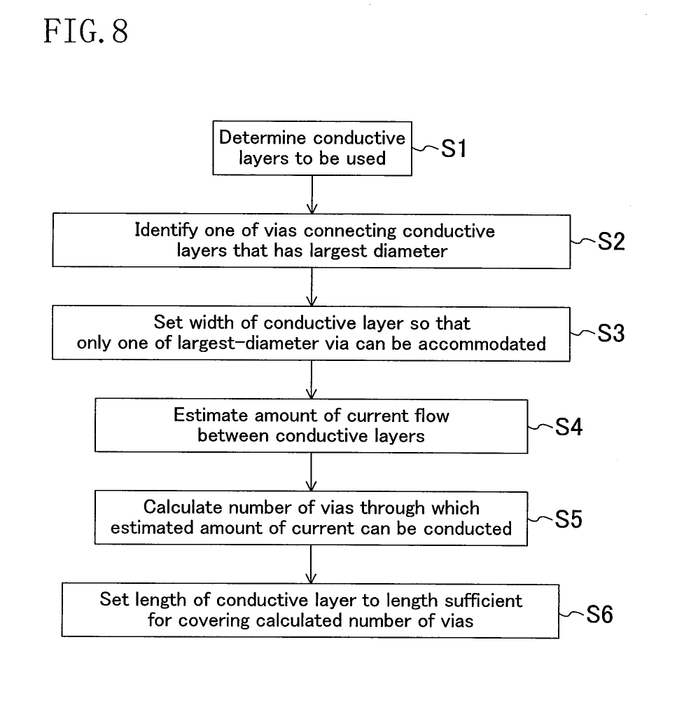

A signal terminal on an I/O cell is designed through a procedure as shown in FIG. 8. First, in step S1, the process determines how many conductive layers are to be used to form the signal terminal. Then, in step S2, the process determines the diameter of the largest one of vias for connecting adjacent conductive layers. Then, in step S3, the process sets the width of the conductive layers so that only one via of the largest diameter can be accommodated.

Then, the length of the conductive layers is determined. First, in step S4, the process estimates the amount of current flow between adjacent conductive layers. Then, in step S5, the process calculates the number of vias through which the amount of current can be conducted. Then, in step S6, the length of each conductive layer is set to a length sufficient for covering the calculated number of vias.

What is claimed is:

1. A semiconductor integrated circuit, comprising:
an I/O cell including one or more signal terminals and being capable of inputting, outputting or inputting/outputting a signal via the signal terminal; and
an interconnect wiring for connecting the signal terminal of the I/O cell to an internal circuit, wherein:
the signal terminal of the I/O cell is formed by a plurality of conductive layers;
adjacent ones of the plurality of conductive layers are connected together by one or more vias; and
a broadest conductive layer, being a broadest one of the plurality of conductive layers, has a width such that only one largest-diameter via having a largest diameter among all the vias can be accommodated.

2. The semiconductor integrated circuit of claim 1, wherein the plurality of conductive layers have a same width.

3. The semiconductor integrated circuit of claim 1, wherein at least two of the plurality of conductive layers have different widths from each other.

4. The semiconductor integrated circuit of claim 1, wherein:
the broadest conductive layer is an uppermost one of the plurality of conductive layers and has a largest thickness among the plurality of conductive layers; and
the largest-diameter via is a via that connects the uppermost conductive layer with another one of the plurality of conductive layers immediately below the uppermost conductive layer.

5. The semiconductor integrated circuit of claim 1, wherein a width of the broadest conductive layer is smaller than twice the diameter of the largest-diameter via.

6. The semiconductor integrated circuit of claim 1, wherein a width of the broadest conductive layer is larger than the diameter of the largest-diameter via.

7. The semiconductor integrated circuit of claim 1, wherein a width of the broadest conductive layer is equal to the diameter of the largest-diameter via.

8. The semiconductor integrated circuit of claim 1, wherein a width of the broadest conductive layer is smaller than the diameter of the largest-diameter via.

9. The semiconductor integrated circuit of claim 1, wherein for any pair of adjacent ones of the plurality of conductive layers, one or more vias for connecting the adjacent conductive layers together are arranged in a longitudinal direction of the conductive layers.

10. The semiconductor integrated circuit of claim 1, wherein with vias other than the largest-diameter via, more than one of such vias are arranged in a width direction of the conductive layer to which the vias are connected.

11. The semiconductor integrated circuit of claim 3, wherein one or more of the conductive layers to which the largest-diameter via is not connected are narrow conductive layers, which are narrower than the broadest conductive layer.

12. The semiconductor integrated circuit of claim 11, wherein a width of the narrow conductive layer is smaller than twice a diameter of the via connected to the narrow conductive layer.

13. The semiconductor integrated circuit of claim 11, wherein a width of the narrow conductive layer is larger than a diameter of the via connected to the narrow conductive layer.

14. The semiconductor integrated circuit of claim 11, wherein a width of the narrow conductive layer is equal to a diameter of the via connected to the narrow conductive layer.

15. The semiconductor integrated circuit of claim 11, wherein a width of the narrow conductive layer is smaller than a diameter of the via connected to the narrow conductive layer.

16. A method for designing a signal terminal on an I/O cell, comprising the steps of:
determining a plurality of conductive layers to be used as the signal terminal on the I/O cell;
obtaining a diameter of one of a plurality of vias each for connecting together adjacent ones of the plurality of conductive layers that has a largest diameter; and
setting a width of one of the plurality of conductive layers to which the largest-diameter via is connected to such a width that only one of the largest-diameter via can be accommodated.

17. The method for designing a signal terminal on an I/O cell of claim 16, further comprising the steps of:
estimating an amount of current flow between adjacent ones of the plurality of conductive layers;
calculating a number of vias through which the estimated amount of current can be conducted; and
setting a length of the plurality of conductive layers to a length sufficient for covering the calculated number of vias.
